(19) United States
(12) Patent Application Publication
(10) Pub. No.: US 2008/0238405 A1
(43) Pub. Date: Oct. 2, 2008

(54) RF measurement system incorporating a ream assembly and method of using the same

(76) Inventors: Todd Steven Marshall, Sunnyvale, CA (US); Rory Lynn Van Tuyl, Los Altos, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/729,105

(22) Filed: Mar. 28, 2007

(51) Int. Cl. G01R 23/16

(52) U.S. Cl. 324/76.12

(57) ABSTRACT

A radio-frequency (RF) measurement system for measuring a reflection coefficient an RF device under test (DUT) incorporates a reflection mode electro-absorption modulator (REAM) assembly coupled to the RF DUT. Also included in the measurement system, is a first optical fiber coupled to the REAM assembly, the first optical fiber configured to propagate a first optical signal into the REAM assembly and propagate a first reflected optical signal out of the REAM assembly. Furthermore, a second optical fiber is also coupled to the REAM assembly, the second optical fiber configured to propagate a second optical signal into the REAM assembly and propagate a second reflected optical signal out of the REAM assembly.

### DESCRIPTION OF THE RELATED ART

A radio-frequency (RF) measurement system is typically used to carry out RF field strength measurements at various points of an RF system. The measurements are then used to calculate parameters such as gain, insertion loss, propagation characteristics, and impedance mismatch of one or more RF components of the system. Unfortunately, due to the intrinsic nature of RF transmission, the introduction of measurement system components (an RF probe, for example) into an RF device under test (DUT) leads to undesired perturbations in the operation of the RF system thereby resulting in inaccurate test results. Additionally, traditional RF measurement systems suffer from limitations associated with measurement system components. For example, a traditional RF measurement system uses flexible coaxial cable or semi-rigid coaxial cable to couple signals to/from the DUT. The lossy nature of these cables places restrictions on the length of cable that can be used as well as the bandwidth of the signals that can be carried over them.

These aspects may be further described using FIG. 1, which shows a prior art RF measurement system configured to test a DUT. In this particular example, a microwave bridge 110 is inserted in-line between an RF signal source 105 and a DUT 115. Insertion of microwave bridge 110 into the path of the RF signal often causes undesirable perturbations, for example, in the form of an insertion loss and/or signal reflections due to impedance mismatch.

In one implementation, microwave bridge 110 incorporates a temperature-sensitive resistor, typically in the form of a metallic or semiconductor film embedded in a probe, which is placed in the path of the RF signal traveling from RF source 105 towards DUT 115. The incident RF signal causes a change in the temperature of the temperature-sensitive resistor thereby leading to a change in its resistance. The change in resistance is measured by passing a current through the temperature-sensitive resistor and measuring the resulting change in voltage, which provides an RF field strength measurement.

In certain cases, the current injection and voltage measurement may be carried out in a measurement device that is incorporated directly into microwave bridge 110 or is located very close to microwave bridge 110. However, these configurations prove impractical under certain situations when a human operator may be required to manually operate the measurement device and collect test results. One example of such an impractical situation may arise when the transmission cabling between RF source 105 and DUT 115 is only accessible at an inconvenient location such as in the air between two transmission towers.

Consequently, in such a situation, the change in voltage may be measured by a remotely-located measurement device such as measurement device 100 that is coupled to microwave bridge 110 via coaxial cable 120. Unfortunately, coaxial cable 120 has an intrinsic attenuation characteristic that leads to an unacceptable level of signal loss over a long distance, as well as bandwidth constraints that impose undesirable limitations upon the types of signals that can be carried over the cable.

Based on the above-mentioned handicaps, an unaddressed need exists in the industry to overcome such deficiencies and inadequacies.

### SUMMARY

A radio-frequency (RF) measurement system for measuring a reflection coefficient an RF device under test (DUT) incorporates a reflection mode electro-absorption modulator (REAM) assembly coupled to the RF DUT. Also included in the measurement system, is a first optical fiber coupled to the REAM assembly, the first optical fiber configured to propagate a first optical signal into the REAM assembly and propagate a first reflected optical signal out of the REAM assembly. Furthermore, a second optical fiber is also coupled to the REAM assembly, the second optical fiber configured to propagate a second optical signal into the REAM assembly and propagate a second reflected optical signal out of the REAM assembly.

### BRIEF DESCRIPTION OF THE DRAWINGS

Many aspects of the invention can be better understood with reference to the following drawings. The components in the drawings are not necessarily to scale. Instead, emphasis is placed upon clearly illustrating the principles of the invention. Moreover, in the drawings, like reference numerals designate corresponding parts throughout the several views.

FIG. 1 shows a prior art RF measurement system.

FIG. 2 shows an RF measurement system incorporating a REAM assembly containing a pair of REAM transducers in an exemplary embodiment in accordance with the invention.

FIG. 3 shows a first embodiment of the pair of REAM transducers of FIG. 2 coupled to an RF transmission medium in an exemplary single-ended configuration in accordance with the invention.

FIG. 4 shows a second embodiment of the pair of REAM transducers of FIG. 2 coupled to a pair of RF transmission media in an exemplary differential configuration in accordance with the invention.

FIG. 5 shows a first exemplary transducer I/O interface configuration for coupling the pair of REAM transducers to an RF transmission medium in an exemplary implementation in accordance with the invention.

FIG. 6 shows a second exemplary transducer I/O interface configuration for coupling the pair of REAM transducers to an RF transmission medium in another exemplary implementation in accordance with the invention.

FIG. 7 shows an RF measurement system incorporating the REAM assembly of FIG. 3 together with additional components in an exemplary embodiment in accordance with the invention.

FIG. 8 shows a four-port representation of the REAM assembly of FIG. 7 for describing certain measurement features.

FIG. 9 shows RF signal flows associated with four ports of the REAM assembly of FIG. 8 when an open circuit load is coupled to the REAM assembly.

FIG. 10 shows RF signal flows associated with four ports of the REAM assembly of FIG. 8 when a short circuit load is coupled to the REAM assembly.

FIG. 11 shows RF signal flows associated with four ports of the REAM assembly of FIG. 8 when a characteristic impedance load is coupled to the REAM assembly.

FIGS. 12 A-C show a flowchart for a method of measuring a reflection coefficient of a DUT in an exemplary embodiment in accordance with the invention.

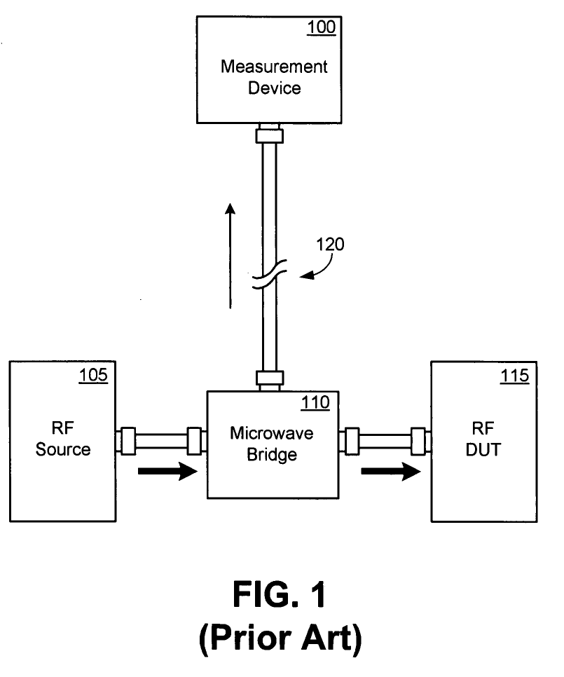

### DETAILED DESCRIPTION

A radio-frequency (RF) measurement system in accordance with the invention includes a reflection mode electro-absorption modulator (REAM) assembly that is used to carry out RF measurements. The REAM assembly contains a pair of REAM transducers coupled to an RF transmission medium at two locations separated from one another by a pre-determined distance. Each of the REAM transducers is individually provided an input optical signal. The input optical signals enter the REAM transducers and undergo modulation as a result of RF energy being incident upon the REAM transducers. The modulated optical signals are then individually propagated over a pair of optical fibers to a signal analyzer that is used to carry out certain RF measurements.

In one exemplary application, an RF source is coupled to one end of the RF transmission medium and an RF device under test (DUT) is coupled to the other end. The REAM assembly is then used to obtain a reflection coefficient measurement of the DUT.

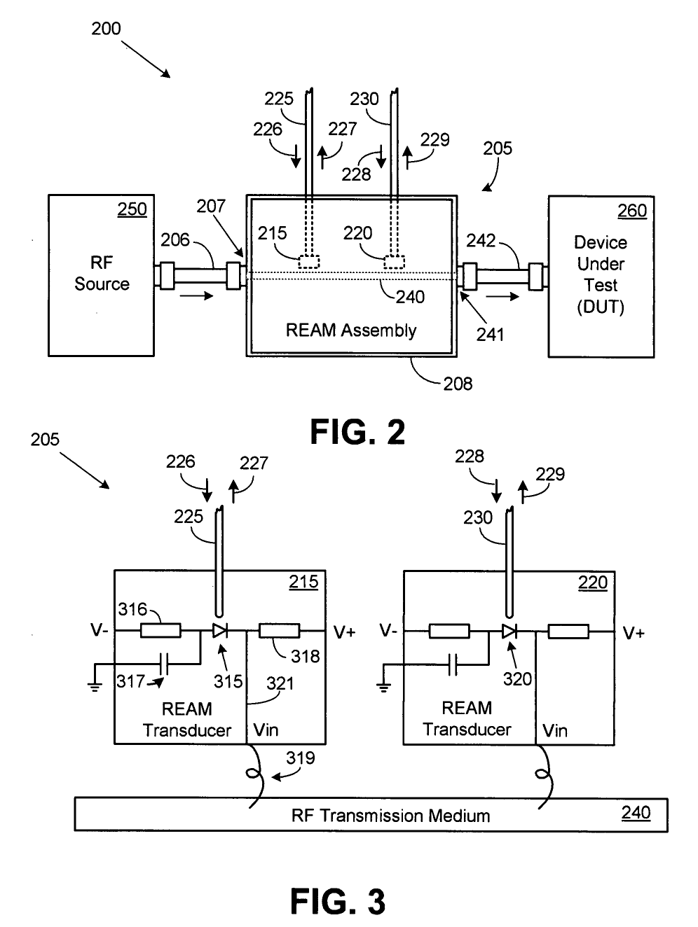

These and other aspects of the invention will now be described below using various drawings. FIG. 2 shows an RF measurement system 200 incorporating a REAM assembly 205 in an exemplary embodiment in accordance with the invention. An RF source 250 is coupled to a first port 207 of REAM assembly 205 through a first RF cable 206. A DUT 260 is coupled to a second port 241 of REAM assembly 205 through a second RF cable 242. An RF transmission medium 240 provides an RF transmission path between first port 207 and second port 241. RF transmission medium 240 of FIG. 2 symbolically represents various types of RF transmission media that may be used in alternative embodiments. A few examples of such media include: a microwave stripline, a microstrip, a pair of microwave striplines, a pair of microstrips, a waveguide, a wire, and a metal track on a substrate. Each of these media may have different characteristic impedances. For example, the metal track may be designed to have a characteristic impedance of 50 ohms in a first application and 75 ohms in a second application. RF transmission medium 240 may also be referred to herein using alternative terms known in the art, such as a transmission path and a transmission line.

REAM assembly 205 contains a pair of REAM transducers 215 and 220 that are coupled to RF transmission medium 240 at two locations separated from one another. A REAM transducer may be broadly described as a device based on multiquantum-well (MQW) technology that is used to reflect an incident light beam back into an optical fiber in proportion to a voltage incident upon the transducer. Typically, a REAM transducer has high electrical input impedance and minimal input capacitance, thereby making the transducer an attractive choice for probing RF signals. Additionally, unlike an electrical signal traveling over a traditional coaxial cable, the light beam reflected by the REAM transducer can be propagated over very long distances via an optical fiber. Several publications authored by the inventors provide further details on REAM devices and applications. Specific attention is drawn to a first publication titled “Testing High-Frequency Electronic Signals With Reflection-Mode Electroabsorption Modulators” by Rory L. Van Tuyl et al, published in IEEE Transactions on Microwave Theory and Techniques, Vol. 54, No. 12, December 2006, which is incorporated herein by reference in its entirety. Attention is also drawn to a second publication titled “A Calibrated Microwave Directional Bridge for Remote Network Analysis through Optical Fiber” by Todd S. Marshall and Rory Van Tuyl, published in IEEE MTT-S International Microwave Symposium Digest, San Francisco, Calif., Jun. 11-16, 2006, ThPK-2, which is also incorporated herein by reference in its entirety.

A first optical fiber 225 is optically coupled to REAM transducer 215. Optical fiber 225 is configured to propagate a first optical signal 226 generated by an optical signal generator (not shown) towards REAM transducer 215. RF energy traveling in one or both directions of RF transmission medium 240 is coupled into REAM transducer 215, and modulates a reflected optical signal 227 that then propagates via optical fiber 225 in a direction opposite to that of first optical signal 226. Reflected optical signal 227 provides measurement information for measuring the RF field strength at the location where REAM transducer 215 couples to RF transmission medium 240.

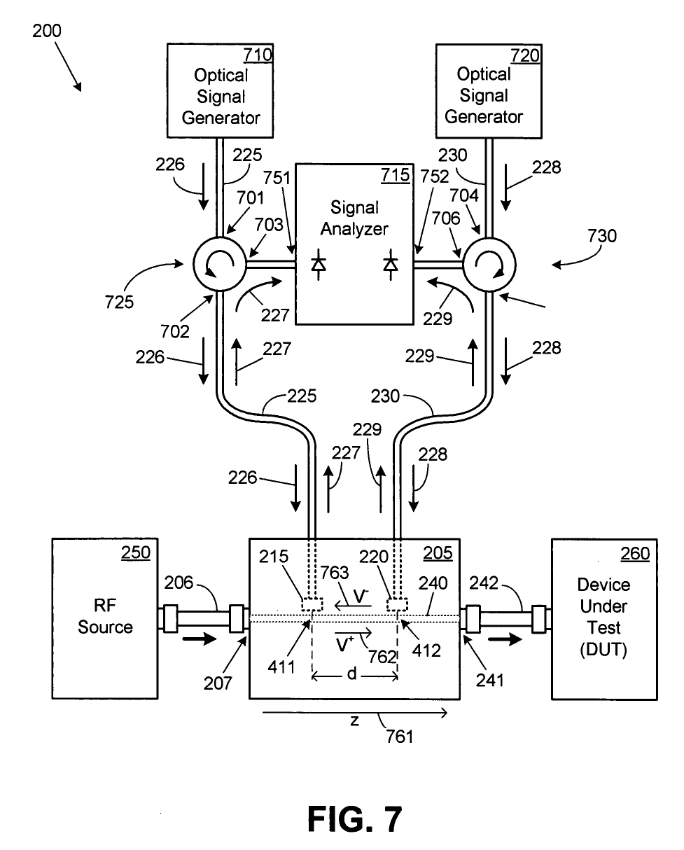

REAM transducer 220 is further associated with a second optical fiber 230 and is configured to operate in a manner similar to that of REAM transducer 215 and optical fiber 225. Reflected optical signal 229 provides measurement information for measuring the RF field strength at the location where REAM transducer 220 couples to RF transmission medium 240. Reflected optical signal 229 is typically used in conjunction with reflected optical signal 227 for performing various RF measurements such as determining the reflection coefficient of DUT 260. These aspects will be elaborated upon below in further detail using FIGS. 7-12.

REAM assembly 205 may be packaged in a variety of ways. In some cases, REAM assembly 205 is a stand-alone assembly, while in other cases REAM assembly 205 may be co-located with other RF circuitry that are not a part of RF measurement system 200.

Specifically, in the example described above, the components of REAM assembly 205 are shown as being housed inside an RF shielded enclosure 208 upon which are mounted RF connectors associated with the two ports 207 and 241. However, in an alternative exemplary embodiment, RF transmission medium 240 is an RF stripline formed on a suitable substrate, alumina for example, and RF source 250 is coupled to RF transmission medium 240 via a wire that is electrically bonded to one end of RF transmission medium 240. A similar bond connection may be provided to couple DUT 260 to the other end of RF transmission medium 240.

As a further example of the variety of packaging options, REAM transducers 215 and 220 may be implemented as sub-assemblies that are mounted on to the substrate described above. The sub-assemblies may be further mounted on a common mounting fixture. These and other variants will be understood by persons of ordinary skill in the art. Consequently, various other packaging options will not be described herein, so as to avoid distraction from pertinent aspects of the invention that require more elaboration.

FIG. 3 shows a first embodiment of REAM assembly 205, where REAM transducers 215 and 220 are each coupled to RF transmission medium 240 in a single-ended configuration. REAM transducer 215 contains a REAM device 315, which is pictorially depicted in FIG. 3 as a diode merely for ease of description. Optical fiber 225 is optically aligned to REAM device 315 so as to direct first optical signal 226 towards REAM device 315 and also to propagate reflected optical signal 227 away from REAM device 315. In certain applications, an optical lens and/or other optical circuitry may be used to carry out the optical coupling between optical fiber 225 and REAM device 315.

Optical fiber 230 is optically aligned to REAM device 320 so as to direct second optical signal 228 towards REAM device 320 and also to propagate reflected optical signal 229 away from REAM device 320.

REAM device 315 is biased using a pair of voltages designated as V+ and V−. The biasing is selected to place REAM device 315 at a substantial center of a linear range of operation. Capacitor 317 provides AC-coupling to ground for one end of REAM device 315, while the other end of REAM device 315 is coupled to a connection 321 that is designed to carry an RF signal (Vin) from RF transmission medium 240 into REAM device 315. RF signal Vin varies the biasing applied to REAM device 315 thereby modulating the first optical signal 226, which in turn leads to the generation of reflected optical signal 227. Various parameters of reflected optical signal 227 may be used to carry the modulation information. As one among several examples, the amplitude of reflected optical signal 227 is used as an indicator of the amplitude of RF signal Vin.

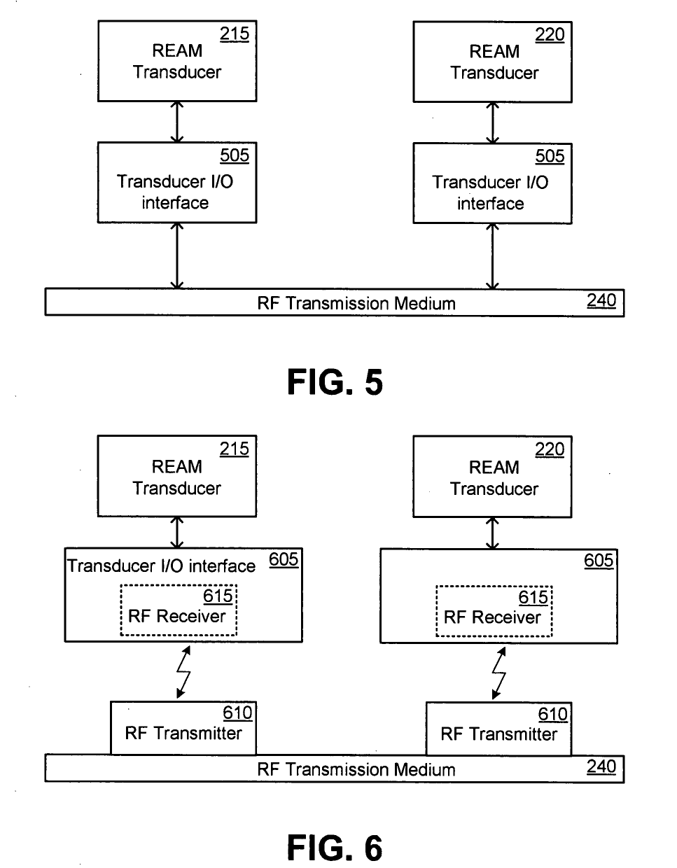

The configuration shown in FIG. 3 is a representative example of a single-ended mode of operation where REAM transducer 215 is coupled to a single RF transmission medium 240, which is for example, a 50 ohm transmission line. In this exemplary embodiment, a metal wire 319 is used to couple REAM transducer 215 to RF transmission medium 240. However, in other embodiments other coupling circuitry may be used. A few examples are provided below using FIGS. 5 and 6.

In the example provided above, the operation and circuitry of REAM transducer 220 is similar to that of REAM transducer 215. However, in certain other embodiments the two REAM transducers may incorporate different hardware and be coupled to RF transmission medium 240 in a dissimilar manner. Additional details on REAM transducers and operation may be obtained from Patent Application Publication US 2005/0185246 A1 titled: “Device for Remotely Stimulating and Measuring Electronic Signals through a Fiber Optic Cable,” inventor Rory L. Van Tuyl, which is incorporated herein by reference in its entirety.

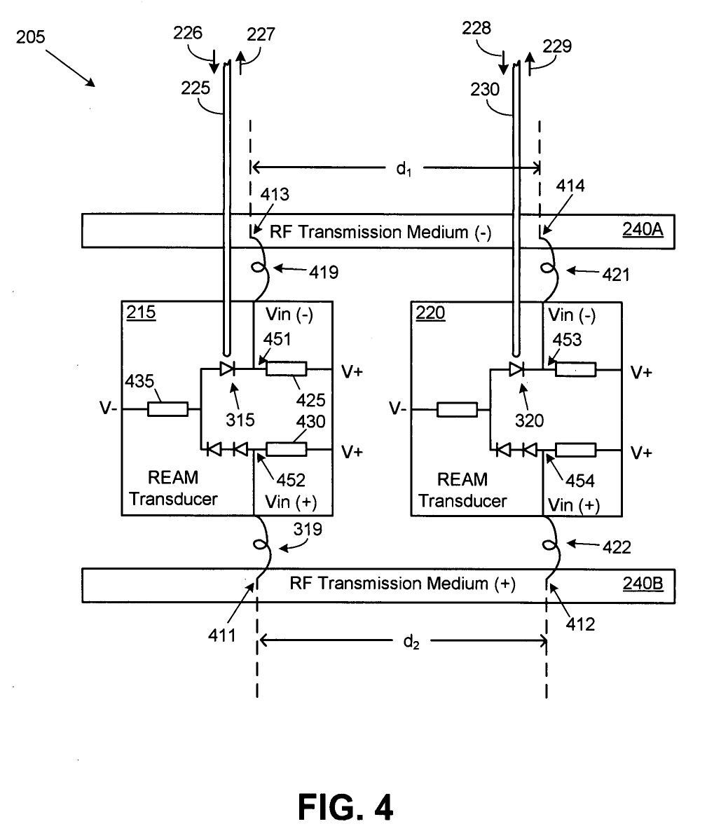

FIG. 4 shows a second embodiment of REAM assembly 205, where REAM transducers 215 and 220 are coupled to a differential RF transmission medium (240A and 240B) for operating in a differential mode of measurement. Optical fiber 225 is optically aligned to REAM device 315 so as to direct first optical signal 226 towards REAM device 315 and also to propagate reflected optical signal 227 away from REAM device 315. Similarly, optical fiber 230 is optically aligned to REAM device 320 so as to direct second optical signal 228 towards REAM device 320 and also to propagate reflected optical signal 229 away from REAM device 320.

REAM transducer 215 contains REAM device 315 together with additional circuit components that are used to configure REAM transducer as a differential transducer. Specifically, bias voltage V+ is applied a first resistor 425 that is used for biasing REAM device 315 in one current path, and is also used to bias a second resistor 430 that is used for biasing a pair of diodes in a second current path independent of the first. The pair of devices is selected to mirror certain characteristics of REAM device 315 so as to provide substantially similar biasing currents in the two current paths. A resistor 435, which is coupled to bias voltage V− provides a common biasing current path to the two current paths.

In this exemplary embodiment, a pair of transmission lines, designated as 240A and 240B, constitutes the differential RF transmission medium. A first metal wire 319 is used to couple REAM transducer 215 to a first location 411 of RF transmission medium 240B and a second metal wire 422 is used to couple REAM transducer 220 to a second location 412 of RF transmission medium 240B. Locations 411 and 412 are separated from each other by a distance d₂.

A third metal wire 419 is used to couple REAM transducer 215 to a first location 413 of RF transmission medium 240A and a fourth metal wire 421 is used to couple REAM transducer 220 to a second location 414 of RF transmission medium 240A. Locations 413 and 414 are separated from each other by a distance d₁. In one embodiment, the two separation distances designated d₁ and d₂ are equal to one another. However, in an alternative embodiment, the two separation distances are not equal.

First metal wire 319 couples a positive polarity RF signal Vin (+) from location 411 into a first circuit node 452 of the differential circuit contained in REAM transducer 215, while second metal wire 419 couples a negative polarity RF signal Vin (−) from location 413 into a second circuit node 451 of the differential circuit contained in REAM transducer 215. Third metal wire 422 couples a positive polarity RF signal Vin (+) from location 412 into a first circuit node 454 of the differential circuit contained in REAM transducer 220, while fourth metal wire 421 couples a negative polarity RF signal Vin (−) from location 414 into a second circuit node 453 of the differential circuit contained in REAM transducer 220.

The pair of differential RF signals that are coupled into REAM transducer 215 modulate REAM device 315 thereby leading to the generation of reflected optical signal 227. Similarly, the pair of differential RF signals that are coupled into REAM transducer 220 modulate REAM device 320 thereby leading to the generation of reflected optical signal 229 that is propagated through optical fiber 230.

While metal wires 319, 422, 419, and 421 have been used above for purposes of description in this exemplary embodiment, in other embodiments other types of coupling elements may be used. Furthermore, while the individual circuitry contained in each of REAM transducers 215 and 220 is shown as being similar to each other in this exemplary embodiment, in alternative embodiments the two REAM transducers may incorporate different hardware and be coupled to RF transmission medium 240A and 240B using different types of coupling elements.

FIG. 5 shows a first exemplary transducer I/O interface 505 for coupling the pair of REAM transducers to an RF transmission medium 240 in an exemplary implementation in accordance with the invention. Transducer I/O interface 505 contains various types of hardware to provide coupling between each of the REAM transducers and RF transmission medium 240. A few non-limiting examples include a metal wire, a metal trace on a substrate, an inductive coupler, and a capacitive coupler.

FIG. 6 shows a second exemplary transducer I/O interface 605 for coupling the pair of REAM transducers to an RF transmission medium 240 in another exemplary implementation in accordance with the invention. In this case, transducer I/O interface 605 includes an RF receiver 615 that operates in conjunction with RF transmitter 610 to provide wireless interconnectivity between each of the REAM transducers and RF transmission medium 240. In an alternative embodiment, RF transmitter 610 may be replaced by an RF transceiver; and RF receiver 615 may be correspondingly replaced by an RF transceiver as well.

FIG. 7 shows RF measurement system 200 incorporating REAM assembly 205 together with additional components in an exemplary system embodiment in accordance with the invention. Optical signal generator 710 is used to generate first optical signal 226. In one exemplary implementation, optical signal generator 710 is a laser transmitter that generates first optical signal as a continuous wave (CW) optical signal. In another exemplary implementation, optical signal generator 710 uses a laser transmitter to generate first optical signal as a non-CW optical signal, for example a modulated optical signal. First optical signal 226 is propagated over optical fiber 225 to an input port 701 of optical circulator 725. Optical circulator 725 circulates first optical signal 226 from input port 701 to a bi-directional port 702 from which first optical signal 226 is propagated to REAM transducer 215.

REAM assembly 215 generates first reflected optical signal 227 as was described above. First reflected optical signal 227 is propagated over optical fiber 225 towards bi-directional port 702 of optical circulator 725. Optical circulator 725 circulates the first reflected optical signal 227 from bi-directional port 702 to an output port 703 from which the first reflected optical signal 227 is propagated to a first input port 751 of signal analyzer 715.

The operation of optical signal generator 720, optical circulator 730 and REAM transducer 220 is similar to that of optical signal generator 710, optical circulator 725 and REAM transducer 215 and will be understood accordingly. In certain embodiments, optical signal generator 710 and 720 are replaced by a single optical signal generator and optical circulators 725 and 730 are commonly provided an input optical signal generated by the single optical signal generator.

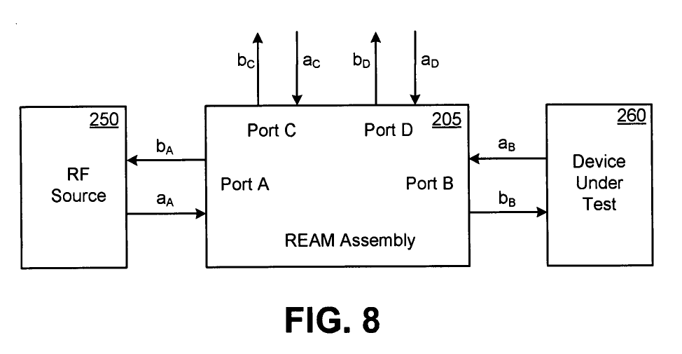

Second reflected optical signal 229 is routed from optical circulator 730 towards a second input port 752 of signal analyzer 715. Signal analyzer 715 incorporates a pair of opto-electronic (O/E) converters, photodetectors for example, that are configured to receive the first and the second reflected optical signals and convert these optical signals to corresponding electrical signals. The electrical signals are then processed to obtain measurement information of DUT 260. For example, the electrical signals are processed to obtain a reflection coefficient of DUT 260. The method of obtaining the reflection coefficient is described below using FIGS. 8-12.

Different types of circuits may be used to implement signal analyzer 715 depending upon the type of RF measurement to be carried out. In one exemplary embodiment, signal analyzer 715 is a network analyzer with internal or external O/E converters. In another exemplary embodiment, signal analyzer 715 is a vector network analyzer incorporating a pair of PIN detectors. In general, signal analyzer 715 is configured to measure magnitude and phase of a pair of signals.

The first reflected optical signal 227 provides measurement information for determining the RF voltage present at location 411 of RF transmission medium 240. The second reflected optical signal 229 provides measurement information for determining the amplitude of an RF voltage present at location 412, which is located at a distance d from location 411.

Attention is now drawn to RF signal flows inside REAM assembly 205. As explained above, RF source 250 provides an RF signal that propagates over first RF cable 206 into first port 207 of REAM assembly 205. The RF signal propagates through REAM assembly 205 in a forward direction z indicated by arrow 761. The instantaneous voltage present in the forward-traveling RF signal is represented by V⁺ (i.e. V plus). After propagating through REAM assembly 205, the RF signal exits through second port 241 of REAM assembly 205 and thereon through second RF cable 242 into DUT 260. In an ideal measurement set-up where the transmission medium, as well as cables and other test components do not adversely affect the measurement, the RF signal would be affected solely by DUT 260. DUT 260 may present an impedance mismatch that gives rise to a reflected RF signal that propagates in a reverse direction, indicated by arrow 763, through REAM assembly 205. The instantaneous voltage present in this reverse-traveling RF signal is represented by V⁻ (i.e. V minus) In such an idealized set-up, the total voltage present between locations 411 and 412 can be obtained by summing the forward and reverse-traveling signals using the following equation:

V(z)=V⁺e^{-γz}+V⁻e^{γz} (1)

Unfortunately, in a real-world situation the various components such as second port 241, second RF cable 242, and the RF connectors on the ports of REAM assembly 205 each constitute an impedance discontinuity that leads to signal reflections. Consequently, when measuring the reflection coefficient of DUT 260, the reflections generated by other components such as second port 241 and second RF cable 242 have to be taken into consideration so as to eliminate them and obtain an accurate measurement of the reflection coefficient of DUT 260. Additionally, the non-ideal performance of various components such as REAM sensors 215 and 220, and the O/E converters in measurement system 715, has also to be accounted for when carrying out real-world measurements. The accommodation for such real-world limitations is carried out by performing a calibration process upon RF measurement system 200 as described below.

FIG. 8 shows a four-port representation of REAM assembly 205 for describing certain measurement features pertinent for performing a calibration process as well as for carrying out measurements upon DUT 260. REAM assembly 205 has a Port A to which is coupled to RF source 250, and a Port B to which is coupled to DUT 260. Ports C and D are measurement ports to which are coupled a pair of optical fibers, such as optical fibers 225 and 230. Optical fibers 225 and 230 are coupled to REAM transducers 215 and 220 (not shown) in accordance with the invention. Each port is shown with an input RF signal and an RF output signal, designated aₓ and bₓ (x=a, b, c, d respectively). While the two signals may be represented using various parameters such as RF power, RF current, and RF voltage; for purposes of description, RF voltage is used below.

The reflection coefficient of DUT 260 can be determined by the following equation:

p=a_{B}/b_{B} (2)

Because each of the REAM transducers 215 and 220 (not shown) present a high impedance and no RF signals are injected into ports C and D, a_{C} and a_{D} are each equal to zero. A generalized scattering matrix representation is defined by the following equation:

bᵢ=S_{iA}a_{A}+S_{iB}a_{B} (3)

where i=[A, B, C, D]. The desired ratio ρ of equation (2) can be calculated using the measured quantities b_{C} and b_{D} as described below.

Firstly, a ratio of the measured quantities b_{C} and b_{D} is defined as:

χ=b_{C}/b_{D} (4)

The following expression is obtained by algebraic manipulation of equation (3) using (2):

−c₀+ρψc₁+ψc₂=ρ (5)

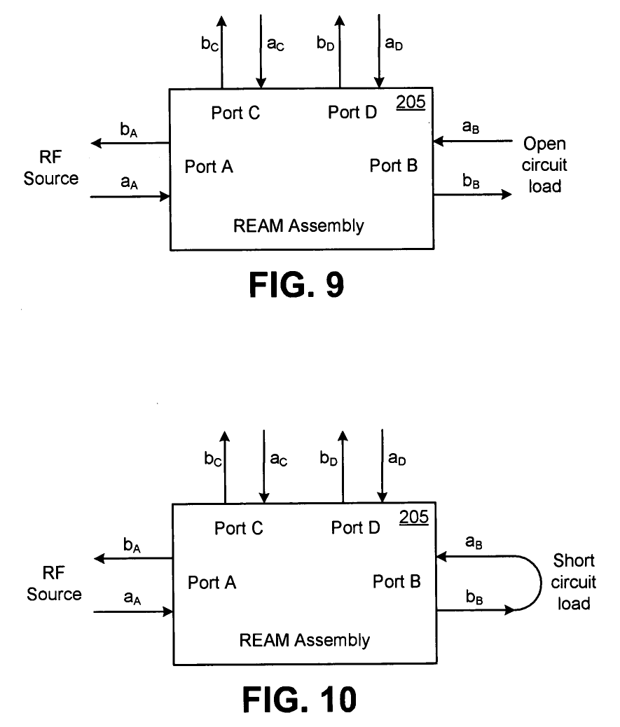

Expression (5) is an equation containing three unknowns cᵢ that can be identified using three calibration standards. An open circuit load, a short circuit load, and a characteristic impedance load constitute a convenient set of calibration standards. FIGS. 9, 10, and 11 show these loads respectively coupled to REAM assembly 205. The characteristic impedance load is selected based on the system impedance, whereby for example, the characteristic impedance is equal to 50 ohms when the system impedance is 50 ohms. By measuring b_{C} and b_{D} for each of these calibration standards the coefficients cᵢ are determined from the following equations:

c₀=(−ψ₀ψ_{z}+ψₛψ_{z})/Δ (6)

c₁=(−ψ_{z}+ψₒ−ψ_{z}+ψₛ)/Δ (7)

c₂=(ψₛ−ψₒ)/Δ (8)

Δ=−ψ₀ψ_{z}+ψₛ(ψₒ−ψ_{z})+ψₛψₒ (9)

where ψ₀, ψₛ, and ψ_{z} are the measured voltage ratios with the open, short, and characteristic impedance load calibration standards respectively coupled to REAM assembly 205. The load calibration standards may be then replaced with DUT 260 to determine ψ₁, the desired reflection coefficient, which is then, determined using the following equation:

ρ=(c₂ψ₁−c₀)/(1−c₁ψ₁) (10)

The denominator of equation (10) can be equal to zero under certain conditions. Specifically, the denominator is equal to zero when REAM transducers 215 and 220 are separated by a separation distance d that is an integer multiple of the half-guide wavelength (λ_{g}/2) of RF transmission medium 240, the separation distance d being defined as:

d=n(λ_{g}/2) (11)

where n={0, 1, 2, . . . }. At the frequency where the denominator goes to zero, the calculation of ρ becomes highly sensitive to the finite uncertainty in the measurement of ψ₁. As a consequence, the upper bandwidth limit of REAM assembly 205 is determined by the separation distance d between REAM transducers 215 and 220 as follows:

fₘₐₓ₌₍v_{g}/2d) (12)

where v_{g} is the group velocity for an RF signal propagating through RF transmission medium 240 (not shown).

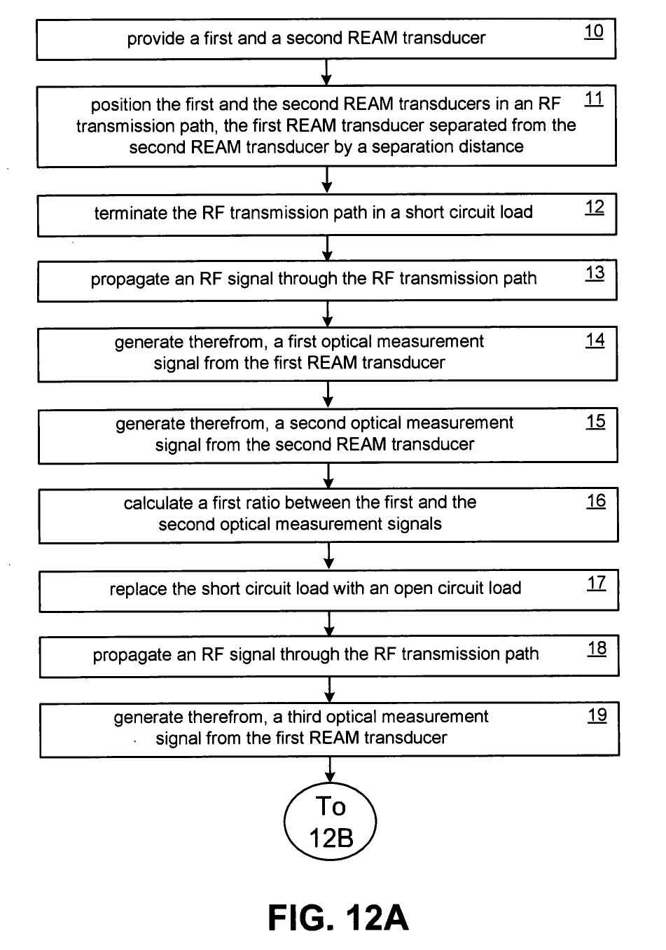

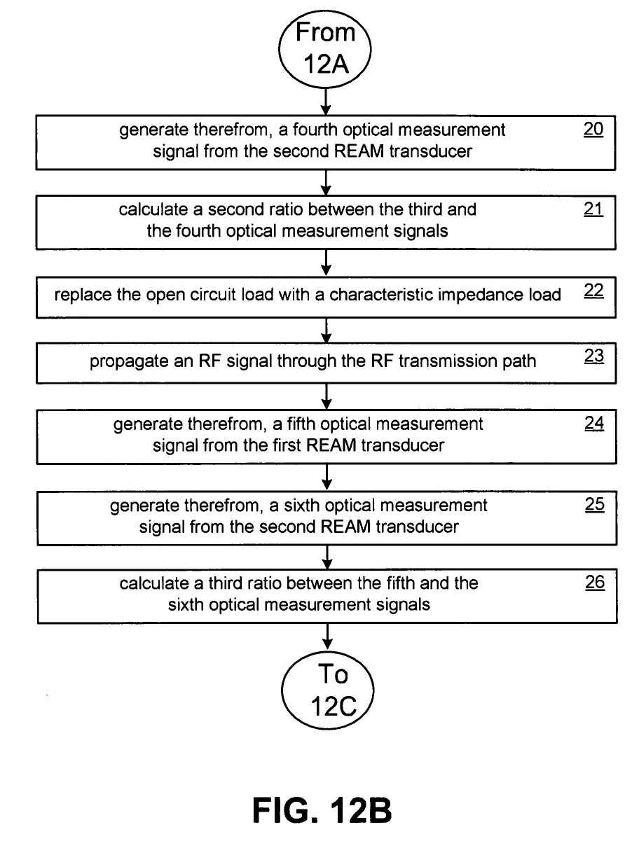

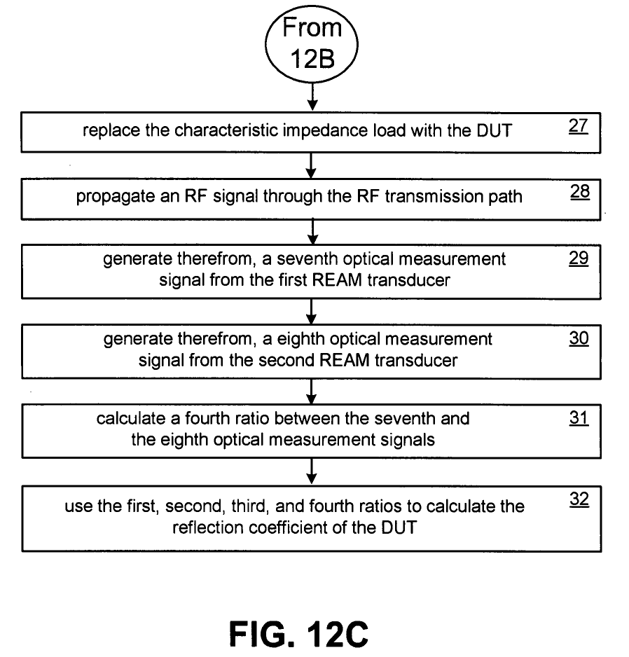

FIGS. 12A-C show a flowchart for a method of measuring a reflection coefficient of a DUT in an exemplary embodiment in accordance with the invention. For purposes of understanding the description, FIGS. 9-11 may be used together with FIGS. 4 and 7 as exemplary hardware configurations for implementing the various blocks of the flowchart. It will be understood that the various blocks of the flowchart have been described in a particular sequence solely for purposes of description. However, the various blocks can be implemented in several alternative sequences in other embodiments.

Among FIGS. 12A-C, the portion of the flowchart shown in FIGS. 12A-B describes a process for calibrating the RF measurement system using a short circuit load, an open circuit load and a characteristic impedance load, while the portion shown in FIG. 12C describes a method for measuring the reflection coefficient of a DUT.

In block 10 of FIG. 12A, a pair of REAM transducers are provided. In block 11, the two REAM transducers are positioned in an RF transmission path separated from one another by a separation distance (indicated by d₁, d₂ in FIG. 4; and d in FIG. 7). In block 12, the RF transmission path is terminated in a short circuit load (FIG. 10). In block 13, an RF signal is propagated through the RF transmission path as described above. The RF signal is incident upon the first REAM transducer resulting in generation of a first optical signal as disclosed in block 14. The first optical measurement signal is propagated over the first optical fiber to a signal analyzer.

The RF signal is further incident upon the second REAM transducer resulting in generation of a second optical signal as disclosed in block 15. The second optical measurement signal is propagated over the second optical fiber to the signal analyzer. The signal analyzer is configured to calculate a first ratio (ψₛ=b_{C}/b_{D}) between the first and the second optical measurement signals. This action is shown in block 16 of the flowchart.

In block 17, the short circuit load is replaced with an open circuit load (FIG. 9). In block 18, the RF signal is again propagated through the transmission path and in blocks 19 and 20 a third and a fourth optical measurement signal is generated respectively from the two REAM transducers. In block 21, the signal analyzer is used to calculate a second ratio (ψₒ=b_{C}/b_{D}) between the third and the fourth optical measurement signals.

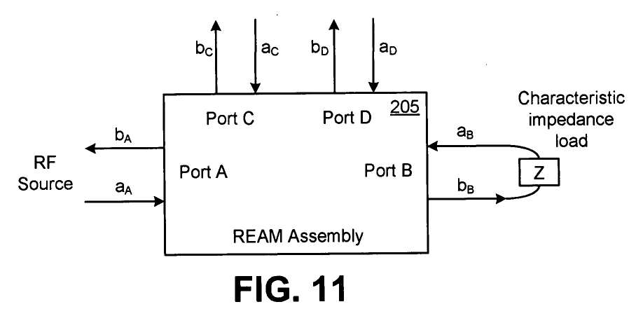

In block 22, the open circuit load is replaced with a characteristic impedance load (FIG. 11). In block 23, the RF signal is again propagated through the transmission path and in blocks 24 and 25 a fifth and a sixth optical measurement signal is generated respectively from the two REAM transducers. In block 26, the signal analyzer is used to calculate a third ratio (ψ_{z}=b_{C}/b_{D}) between the fifth and the sixth optical measurement signals.

Blocks 10 through 26 constitute the portion of the flow chart used for calibrating the RF measurement system. The ratios ψₛ, ψₒ, ψ_{z} are used to determine the three coefficients c₀, c₁, and c₂ that are plugged into the equation ρ=(c₂ψ₁−c₀)/(1−c₁ψ₁) for determining the reflection coefficient ρ of the DUT. The flowchart for measuring ψ₁ of the equation is carried out via blocks 27 through 32 that are described below.

In block 27, the characteristic impedance load is replaced with the DUT (FIG. 8) assuming that the calibration process has been carried out prior to block 27. In an alternative embodiment, steps 27 through 32 may be implemented first followed by steps 10 through 26 later on. In this latter case, in block 27, the transmission path is terminated in the DUT load.

In block 28, the RF signal is again propagated through the transmission path and in blocks 29 and 30 a seventh and an eighth optical measurement signal is generated respectively from the two REAM transducers. In block 31, the signal analyzer is used to calculate a fourth ratio (ψ₁=b_{C}/b_{D}) between the seventh and the eighth optical measurement signals. In block 32, the first, second, third, and fourth ratios are used to calculate the reflection coefficient of the DUT by determining the coefficients c₀, c₁, and c₂ and plugging them into the equation ρ=(c₂ψ₁−c₀)/(1−c₁ψ₁).

The disclosure describes the invention in detail using illustrative embodiments. However, the invention defined by the appended claims is not limited to the precise embodiments described.

We claim:

1. A radio-frequency (RF) measurement system for measuring a reflection coefficient of an RF device under test (DUT), the system comprising:
a reflection mode electro-absorption modulator (REAM) assembly coupled to the RF DUT;
a first optical fiber coupled to the REAM assembly, the first optical fiber configured to propagate a first optical signal into the REAM assembly and further configured to propagate out of the REAM assembly, a first reflected optical signal; and
a second optical fiber coupled to the REAM assembly, the second optical fiber configured to propagate a second optical signal into the REAM assembly and further configured to propagate out of the REAM assembly, a second reflected optical signal.

2. The RF measurement system of claim 1, further comprising:
a first and a second laser transmitter configured to generate the first and second optical signals respectively; and
a signal analyzer configured to receive the first and second reflected optical signals from the REAM assembly and generate therefrom, the reflection coefficient of the RF DUT.

3. The RF measurement system of claim 2, further comprising:
a first optical circulator configured to receive the first optical signal from the first laser transmitter and route the first optical signal into the first optical fiber, the first optical circulator further configured to receive the first reflected optical signal from the REAM assembly and route the first reflected optical signal to the signal analyzer; and
a second optical circulator configured to receive the second optical signal from the second laser transmitter and route the second optical signal into the second optical fiber, the second optical circulator further configured to receive the second reflected optical signal from the REAM assembly and route the second reflected optical signal to the signal analyzer.

4. The RF measurement system of claim 3, wherein the signal analyzer is a network analyzer.

5. The RF measurement system of claim 4, wherein the network analyzer comprises a pair of photodetectors for converting the first and second reflected optical signals into corresponding electrical signals for analysis in the network analyzer.

6. A reflection mode electro-absorption modulator (REAM) assembly, comprising:
an RF transmission medium configured to propagate an RF signal;
a first REAM transducer coupled to a first location of the RF transmission medium;
a second REAM transducer coupled to a second location of the RF transmission medium, the second location being different than the first location;
a first optical fiber coupled to the first REAM transducer, the first optical fiber configured to propagate a first optical signal into the REAM assembly and further configured to propagate out of the REAM assembly, a first reflected optical signal; and
a second optical fiber coupled to the second REAM transducer, the second optical fiber configured to propagate a second optical signal into the REAM assembly and further configured to propagate out of the REAM assembly, a second reflected optical signal.

7. The REAM assembly of claim 6, wherein the upper bandwidth limit fₘₐₓ of the REAM assembly is equal to (v_{g}/2d) wherein d is the separation distance between the first and second locations of the RF transmission medium and v_{g} is the group velocity for an RF signal propagating through the RF transmission medium.

8. The REAM assembly of claim 6, wherein each of the first and second REAM transducers is provided a voltage bias that is selected to place each of the REAM transducers at substantially the center of a linear operating range.

9. The RF measurement system of claim 6, wherein each of the first and second REAM transducers is configured for a single-ended coupling of each of the transducers to the RF transmission medium.

10. The RF measurement system of claim 6, wherein the RF transmission medium comprises a differential pair of transmission lines and the first REAM transducer comprises a differential pair of connector leads for a differential coupling of the first REAM transducer to the differential pair of transmission lines.

11. The RF measurement system of claim 6, wherein the first REAM transducer is coupled to the first location of the RF transmission medium using one of a) a metal wire, b) an inductive coupling, c) a capacitive coupling, and d) a wireless coupling.

12. The RF measurement system of claim 6, wherein the RF transmission medium comprises one of a) an RF microstrip, b) an RF stripline, and c) a microwave waveguide.

13. A method of measuring a reflection coefficient of an RF device under test (DUT), the method comprising:
providing a first REAM transducer and a second REAM transducer;
positioning the first and the second REAM transducers in an RF transmission path, the first REAM transducer separated from the second REAM transducer by a separation distance;
terminating the RF transmission path in a short circuit load;
propagating an RF signal through the RF transmission path;
generating therefrom, a first optical reflected signal from the first REAM transducer;
generating therefrom, a second optical reflected signal from the second REAM transducer;
calculating a first ratio between the first and second optical reflected signals;
replacing the short circuit load with an open circuit load;
propagating the RF signal through the RF transmission path;
generating therefrom, a third optical reflected signal from the first REAM transducer;
generating therefrom, a fourth optical reflected signal from the second REAM transducer;
calculating a second ratio between the third and fourth optical reflected signals;
replacing the open circuit load with a characteristic impedance load;
propagating the RF signal through the RF transmission path;
generating therefrom, a fifth optical reflected signal from the first REAM transducer;
generating a sixth optical reflected signal from the second REAM transducer;
calculating a third ratio between the fifth and sixth optical reflected signals;
replacing the characteristic impedance load with the DUT;
propagating the RF signal through the RF transmission path;
generating therefrom, a seventh optical reflected signal from the first REAM transducer;
generating therefrom, a eighth optical reflected signal from the second REAM transducer;
calculating a fourth ratio between the seventh and eighth optical reflected signals;
using the first, second, third, and fourth ratios to calculate the reflection coefficient of the DUT.

14. The method of claim 13, wherein the upper bandwidth limit of a measurement system comprising the first and second REAM transducers is equal to a group velocity of the RF signal propagating through the RF transmission path divided by twice the separation distance between the first and second REAM transducers.

15. The method of claim 13, wherein the RF transmission path comprises one of a) an RF microstrip, b) an RF stripline, and c) a microwave waveguide.

16. The method of claim 13, wherein the RF transmission path comprises one of a 50 ohm transmission line and a 75 ohm transmission line.

17. The method of claim 13, further comprising:
transporting the first, third, fifth and seventh optical reflected signals over a first optical fiber optically coupled to a signal analyzer; and
transporting the second, fourth, sixth and eighth optical reflected signals over a second optical fiber optically coupled to the signal analyzer.

18. The method of claim 17, wherein each of the first, second, third, fourth, fifth, sixth, seventh, and eighth optical reflected signals are converted into corresponding voltages that are used to calculate the first, second, third, and fourth ratios.

19. The method of claim 13, further comprising:
configuring one of the first and second REAM transducers as a component of a measurement bridge.

20. The method of claim 13, wherein the separation distance between the first and the second REAM transducers is selected to be a non-integer multiple of the half guide wavelength (λ_{g}/2) of the transmission path.
